(19) United States
(12) Patent Application Publication
(10) Pub. No.: US 2014/0145320 A1
(43) Pub. Date: May 29, 2014

(54) DIE PACKAGE

(71) Applicant: CAMBRIDGE SILICON RADIO LIMITED, Cambridge (GB)

(72) Inventor: Martyn Robert Owen, Cambridge (GB)

(73) Assignee: Cambridge Silicon Radio Limited, Cambridge (GB)

(21) Appl. No.: 13/688,397

(22) Filed: Nov. 29, 2012

(51) Int. Cl. H01L 23/495

(52) U.S. Cl. CPC H01L 23/4952
USPC 257/676

(57) ABSTRACT

An electronic device package including an electronic device within a block of insulating material, for example a QFN package. The paddle may be design to extend beyond the die to allow wirebonding between a region of the paddle and the die. Leads may be extended underneath the die and adhered to the die.

### BACKGROUND

Integrated Circuits (IC) are typically fabricated on a Silicon wafer. The wafer is diced into individual die, each carrying an IC. The die are packaged in a housing to protect the device, for ease of handling, and to provide pads for electrical connection to the IC.

An example of a package type is the Quad Flat No-lead (QFN) package shown in cross-section in FIG. 1. The die 2 is mounted on a paddle 3 using an adhesive 4. Metal pads 5 are electrically connected to the die by wirebonds 6. The die, paddle, and pads are encapsulated in a block of insulating material 7. The pads 5 are exposed on the bottom face of the package to allow electrical connection to a circuit board on which the package is mounted. The paddle is also exposed on the bottom face and may be utilised for a ground connection and for heat-sink contact.

A drawback of the QFN package is that if the pads 5 are located close to the die 2 (to provide a small package) there is limited space available and hence the number of pads is limited. As the size of the device is increased more space becomes available, but the length of the wirebonds increases (as well as the size of the package) and they may not have the required electrical, particularly RF, performance. The pads could be extended towards the die, but such an arrangement leads to an increased surface area of the lead being exposed on the bottom surface of the package which is undesirable. A solution to this is known to be to half-etch the leads to remove their bottom surface such that the full length of the lead is not exposed. However, half-etched leads have reduced physical strength and present difficulties for wirebonding.

The embodiments described below are not limited to implementations which solve any or all of the disadvantages of known QFN packages.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

There is provided an electronic device package, comprising a block of insulating material, having a set of contact pads on a first, bottom, face; an electronic device within the block of insulating material, the contact pads being positioned outside of the area of the electronic device when viewed from the bottom face; at least one electrically conductive lead within the block of insulating material, electrically and physically connected to a contact pad, and extending from that contact pad towards the electronic device, wherein the at least one lead extends underneath the die and is adhered to the bottom face of the electronic device.

The electronic device package may further comprise a paddle within the insulating material having a first face co-planar with the bottom face of the block and a second face parallel with the first face within the insulating material, wherein the bottom surface of the electronic device is adhered to the second face of the paddle, wherein the at least one lead is not connected to the paddle.

The at least one lead may be a half-etched lead.

The device package may be a QFN package.

The at least one lead may extend underneath the die by 400 μm or more.

At least one region of the paddle may extend outside the perimeter of the electronic device when viewed from the bottom face, the at least one region of the paddle extending outside the perimeter of the electronic device forming a contact point for wirebonding to the electronic device.

The at least one lead may be wirebonded to the electronic device.

The at least one region may be wirebonded to the electronic device.

There is also provided an electronic device package, comprising a block of insulating material, having a set of contact pads on a first, bottom, face; a paddle within the insulating material having a first face co-planar with the bottom face of the block and a second face parallel with the first face within the insulating material; and an electronic device within the block of insulating material and on the second face of the paddle; wherein at least one region of the paddle extends outside the perimeter of the electronic device when viewed from the bottom face, the regions of the paddle extending outside the perimeter of the electronic device forming a contact point for wirebonding to the electronic device.

The at least one region may be wire bonded to the electronic device.

The electronic device package may further comprise a set of contact pads on a first, bottom, face, and at least one electrically conductive lead within the block of insulating material, electrically and physically connected to a contact pad, and extending from that contact pad towards the electronic device, wherein the at least one lead extends underneath the die and is adhered to the bottom face of the electronic device, and the at least one lead is not connected to the paddle.

The at least one lead may be a half-etched lead.

The device package may be a QFN package.

The at least one lead may extend underneath the die by 400 μm or more.

The at least one lead may be wirebonded to the electronic device.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a conventional QFN package;

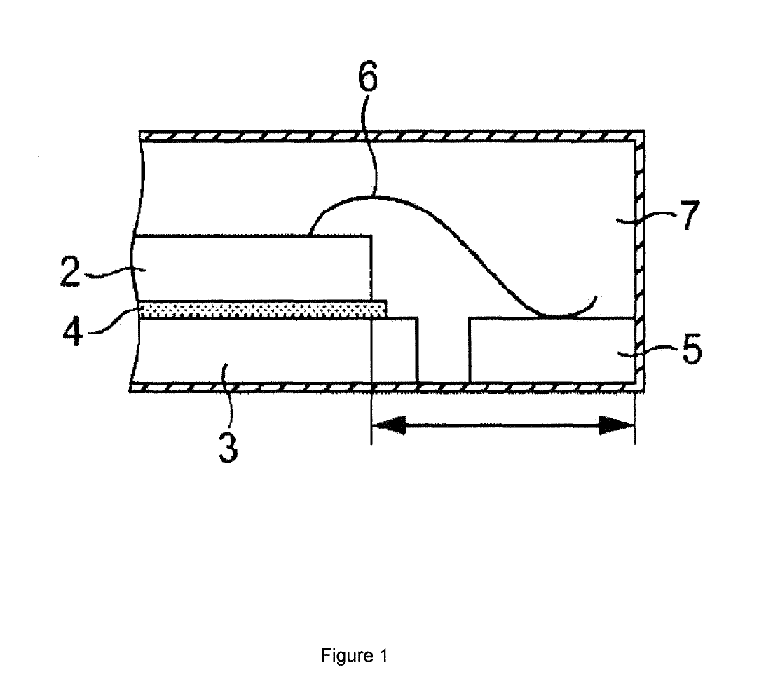

FIG. 2 shows a first modified QFN package;

FIG. 3 shows a second modified QFN package; and

FIG. 4 shows a third modified QFN package.

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

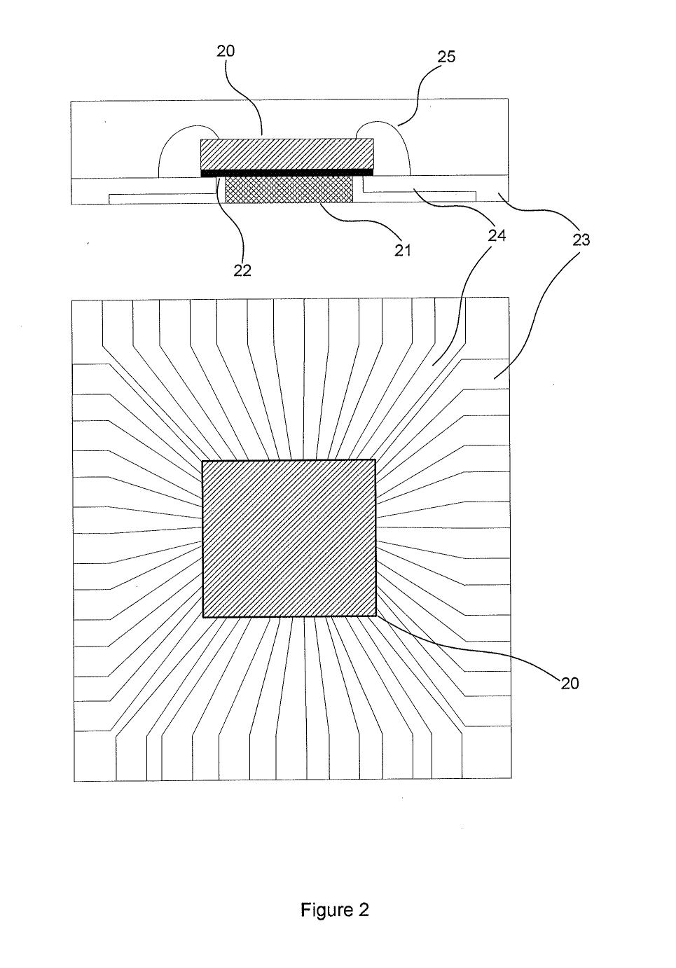

FIG. 2 shows a vertical and horizontal cross-section of a first embodiment of a QFN package. A die 20 is mounted on a paddle 21 in the conventional manner using an adhesive film 22. The paddle 21 is sized such that it does not extend to the edge of the die 20. Pads 23 and half-etched leads 24 are formed in the conventional manner but the leads extend under the die 20 such that the die 20 is adhered to the upper surface of lead 24 by adhesive film 22. The adhesion of the lead 24 to the die 20 attaches the die-end of the lead 24 to the die 20 such that it is held stably during wire-bonding to the lead 24. The wirebond can accordingly be made close to the die 20, thus reducing the length of the wire 25 and avoiding degraded electrical performance of the connection from the die 20 to the lead 24. Adhesive film 22 electrically insulates the lead from the die. Adhesive film 22 may be any known adhesive suitable for the application.

In accordance with standard QFN packaging processes some of the leads 24 may extend to, and be joined to, the paddle 21 to ensure the lead frame is a unitary structure. These leads may also be used as ground connections to the die 20.

In an example the die may extend 600 μm or more beyond the edge of the paddle and the leads may extend 400 μm or more under the die.

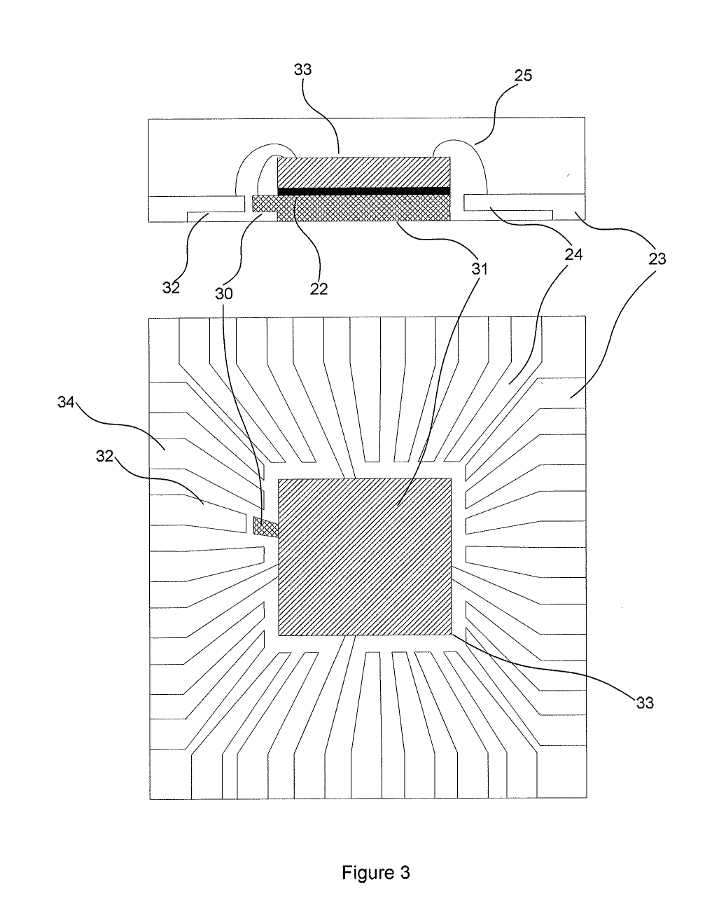

In addition to using leads which provide physical support to the paddle, it is common to require additional ground connections to the die 20. FIG. 3 shows an embodiment of a further QFN package that does not have the die paddle extended beyond the edge of the die. In order to facilitate the ground connections the die paddle is extended only in localized areas that are sufficient for the required number of wirebonds from the die.

A ground lead 30 is provided extending away from the paddle 31 and electrically connected to the paddle 31. The lead 32 which would have been in this location is shortened to leave the required spacing between the leads 30 and 32. The ground lead 30 provides a ground connection to the paddle 31, allowing a wirebond from the die 33 to the lead 30 to provide a ground connection. The lead 32 may be used as a signal connection in the conventional way. Lead 32 is spaced from the die 33 by a greater amount than the normal signal leads 34 and hence the wirebond length to that lead 32 is extended. Although the electrical properties of this lead 32 will be reduced compared to the normal leads 34, this connection can be used for lower-frequency signals and hence this degradation is not a significant impairment. Furthermore, the length of the ground lead 30 can be small, thereby increasing the wirebond length by only a small amount. For example, the ground lead 30 may be 300 μm long. Leads 34 not corresponding to the ground lead 30 can extend close to the die.

In FIG. 3 the ground lead 30 are half-etched in the same manner as the normal leads, but un-etched leads may be utilised. The ground lead 30 is relatively short and therefore it is likely to have sufficient rigidity to allow wirebonding without additional support.

FIG. 3 shows one ground lead 30 extending from the paddle 22, but as will be appreciated any number of such leads may be provided. Furthermore, the ground leads 30 are not necessarily discrete leads, but may be regions extended from the paddle 22 across the width of multiple leads.

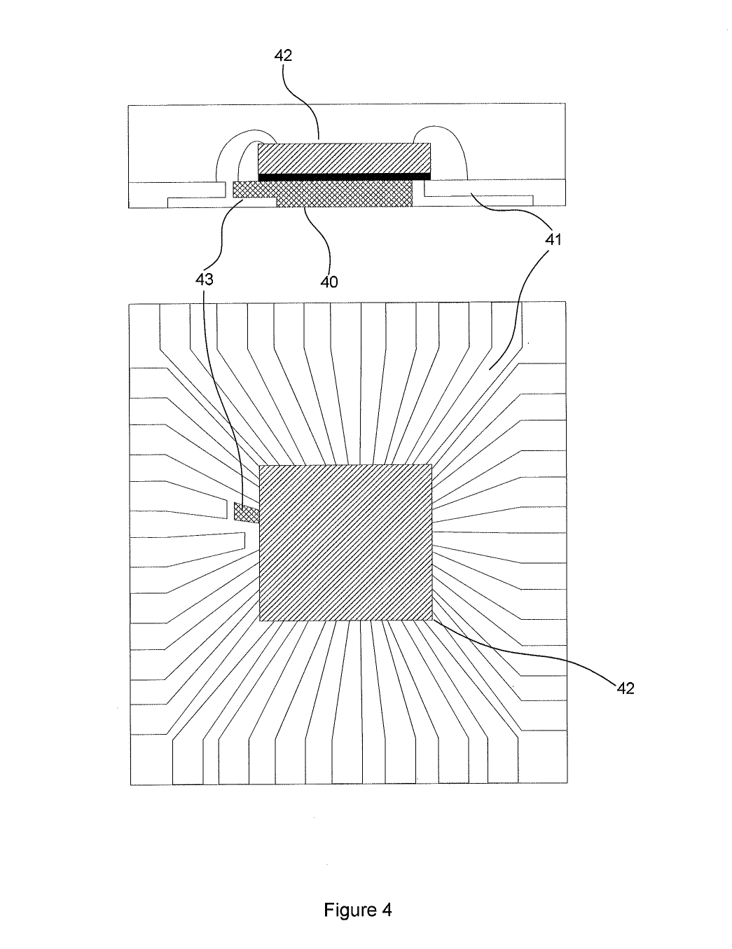

The techniques of FIGS. 2 and 3 may be combined and utilised in the same package as shown in FIG. 4. Paddle 40 is sized such that the perimeter of the paddle lies within the area of the die over some of the perimeter, allowing leads 41 to be adhered to the die 42, as described in relation to the embodiment of FIG. 2. In other areas the paddle 40 extends into ground leads 43, as described in relation to FIG. 3. The principles of the techniques are not affected by this combination. The ground lead 43 will be longer than shown in FIG. 3 as it extends from within the perimeter of the die to beyond the edge of the die to allow wirebonding. However, the lead is attached to the die by the adhesive, thereby provided support during wirebonding.

Conventional QFN manufacturing techniques may be utilised with the embodiments described hereinbefore. After placement of the die on the lead frame and wirebonding processes, the device is encapsulated in a block of insulating material according to standard techniques.

The embodiments described above have been in relation to QFN packages but as will be appreciated the techniques may be applied to other package types having comparable features.

As will be appreciated the term ‘half-etched leads’ is a term of art and does not require that the leads are etched to precisely half their depth. The term is used to describe the use of leads which protrude towards the die from the pads, but have a reduced height such that are not exposed through the bottom of the block of insulating material along their entire length.

Reference has been made to a die, but as will be appreciated the techniques may be utilised to package any appropriate electronic device and this disclosure of not restricted to packaging techniques for semiconductor dies.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

1. An electronic device package, comprising
a block of insulating material, having a set of contact pads on a first, bottom, face;
an electronic device within the block of insulating material, the contact pads being positioned outside of the area of the electronic device when viewed from the bottom face;
at least one electrically conductive lead within the block of insulating material, electrically and physically connected to a contact pad, and extending from that contact pad towards the electronic device, wherein the at least one lead extends underneath the die and is adhered to the bottom face of the electronic device.

2. An electronic device package according to claim 1, further comprising
a paddle within the insulating material having a first face co-planar with the bottom face of the block and a second face parallel with the first face within the insulating material, wherein the bottom surface of the electronic device is adhered to the second face of the paddle, wherein the at least one lead is not connected to the paddle.

3. An electronic device package according to claim 1, wherein the at least one lead is a half-etched lead.

4. An electronic device package according to claim 1, wherein the device package is a QFN package.

5. An electronic device package according to claim 1, wherein the at least one lead extends underneath the die by 400 μm or more.

6. An electronic device package according to claim 1, wherein at least one region of the paddle extends outside the perimeter of the electronic device when viewed from the bottom face, the at least one region of the paddle extending outside the perimeter of the electronic device forming a contact point for wirebonding to the electronic device.

7. An electronic device package according to claim 1, wherein the at least one lead is wirebonded to the electronic device.

8. An electronic device package according to claim 6, wherein the at least one region is wirebonded to the electronic device.

9. An electronic device package, comprising
a block of insulating material, having a set of contact pads on a first, bottom, face;
a paddle within the insulating material having a first face co-planar with the bottom face of the block and a second face parallel with the first face within the insulating material; and
an electronic device within the block of insulating material and on the second face of the paddle;
wherein at least one region of the paddle extends outside the perimeter of the electronic device when viewed from the bottom face, the regions of the paddle extending outside the perimeter of the electronic device forming a contact point for wirebonding to the electronic device.

10. An electronic device according to claim 9, wherein the at least one region is wire bonded to the electronic device.

11. An electronic device package according to claim 9, further comprising
a set of contact pads on a first, bottom, face, and at least one electrically conductive lead within the block of insulating material, electrically and physically connected to a contact pad, and extending from that contact pad towards the electronic device, wherein
the at least one lead extends underneath the die and is adhered to the bottom face of the electronic device, and
the at least one lead is not connected to the paddle.

12. An electronic device package according to claim 9, wherein the at least one lead is a half-etched lead.

13. An electronic device package according to claim 9, wherein the device package is a QFN package.

14. An electronic device package according to claim 9, wherein the at least one lead extends underneath the die by 400 μm or more.

15. An electronic device package according to claim 9, wherein the at least one lead is wirebonded to the electronic device.
